(19) United States
(12) Patent Application Publication
(10) Pub. No.: US 2019/0177215 A1
(43) Pub. Date: Jun. 13, 2019

(54) STRENGTHENED GLASS-BASED ARTICLES HAVING FILLED HOLES AND METHOD OF MAKING THE SAME

(71) Applicant: Corning Incorporated, Corning, NY (US)

(72) Inventors: Yuhui Jin, Painted Post, NY (US); Ekaterina Aleksandrovna Kuksenkova, Painted Post, NY (US)

(21) Appl. No.: 16/323,921

(22) PCT Filed: Aug. 24, 2017
(86) PCT No.: PCT/US17/48307

§ 371 Date: Feb. 7, 2019

Related U.S. Application Data
(60) Provisional application No. 62/381,740, filed on Aug. 31, 2016.

(51) Int. Cl. C03C 21/00; H05K 5/00; H05K 5/03; H05K 1/03; H05K 1/11; H05K 3/40; H05K 1/09; G06K 9/00

(52) U.S. Cl. CPC C03C 21/002; H05K 5/0017; H05K 5/03; H05K 1/0306; H05K 1/115; H05K 1/0271; H05K 1/09; G06K 9/0004; H05K 2201/09509; H05K 2201/068; H05K 3/4038

(57) ABSTRACT

Disclosed is a glass-based article having a glass-based substrate including a first surface, a second surface opposing the first surface, at least one hole formed in the first surface, and a region under a compressive stress extending from the first surface to a depth of compression DOC?1#191 in the glass-based substrate, wherein the compressive stress in the region is greatest at the first surface. An electrically conductive material disposed in the at least one hole, wherein a cross-sectional area of the at least one hole and a cross-sectional area of the electrically conductive material differ by 0.1% or less.

### CROSS-REFERENCE TO RELATED APPLICATIONS

This application claims the benefit of priority under 35 U.S.C. § 119 of U.S. Provisional Application Ser. No. 62/381740 filed on Aug. 31, 2016, the content of which is relied upon and incorporated herein by reference in its entirety.

### BACKGROUND

The disclosure relates to strengthened glass-based articles having at least one hole filled with electrically conductive material and methods of making the same.

Consumer electronic devices with displays often have a strengthened cover substrate made from a glass-based material. The ability to have a conductive pathway through the cover substrate would improve the functioning of certain aspects of the consumer electronic devices, for example, when fingerprint sensors are positioned under the cover substrate. However, the process of making such a strengthened cover substrate with a conductive pathway has been challenging as a result of incompatibility of the process of strengthening a substrate with holes and filling the holes with an electrically conductive material. As such a need exists for creating strengthened glass-based articles having holes filled with electrically conductive material.

### SUMMARY

A first aspect is a glass-based article including a glass-based substrate comprising a first surface, a second surface opposing the first surface, at least one hole formed in the first surface, and a region under a compressive stress extending from the first surface to a depth of compression DOC₁ in the glass-based substrate, wherein the compressive stress in the region is greatest at the first surface; and an electrically conductive material disposed in the at least one hole, wherein a cross-sectional area of the at least one hole and a cross-sectional area of the electrically conductive material differ by 0.1% or less.

A second aspect according to the first aspect, wherein the coefficient of thermal expansion (CTE) of the electrically conductive material is higher than the CTE of the glass-based substrate.

A third aspect according to the first or second aspect, wherein the compressive stress of the glass-based substrate at the first surface is greater than or equal to about 100 MPa.

A fourth aspect according to any one of the first through third aspects, wherein the compressive stress of the glass-based substrate at the first surface is in a range from about 100 MPa to about 1,200 MPa.

A fifth aspect according to any one of the first through fourth aspects, wherein the at least one hole is a through hole that extends from the first surface to the second surface.

A sixth aspect according to any one of the first through fifth aspects, wherein the at least one hole is a blindhole.

A seventh aspect according to any one of the first through sixth aspects, wherein the electrically conductive material is selected from the group consisting of copper, silver, aluminum, titanium, gold, platinum, nickel, tungsten, and magnesium.

An eighth aspect according to any one of the first through seventh aspects, wherein the DOC₁ is at least 20 μm.

A ninth aspect according to any one of the first through eighth aspects, further comprising a second region of compressive stress extending from the second surface to a second depth of compression DOC₂.

A tenth aspect according to the ninth aspect, further comprising a region of central tension located between the regions of compressive stress.

An eleventh aspect according to any one of the first through tenth aspects, wherein the glass-based substrate is glass.

A twelfth aspect according to any one of the first through eleventh aspects, wherein the glass-based substrate is glass-ceramic.

A thirteenth aspect is a consumer electronic product including a housing having a front surface, a back surface and side surfaces; electrical components provided at least partially within the housing, the electrical components including at least a controller, a memory, a fingerprint sensor, and a display, the display being provided at or adjacent the front surface of the housing; and the glass-based article of any one of the first through twelfth aspects disposed over the display, wherein the electrical conductive material provides a conductive pathway for the fingerprint sensor.

A fourteenth aspect is a method of producing a glass-based article including performing a first ion exchange of a glass-based substrate, the glass-based substrate comprising a first surface, a second surface opposing the first surface, and at least one hole formed in the first surface to create a region under a compressive stress extending from the first surface to a depth of compression DOC in the glass-based substrate; filling the at least one hole with an electrically conductive material after ion exchanging the glass-based substrate; and performing a second ion exchange of the glass-based substrate after filling the at least one hole.

A fifteenth aspect according to the fourteenth aspect, wherein a duration of the second ion exchange is shorter than a duration of the first ion exchange.

A sixteenth aspect according to the fifteenth aspect, wherein the duration of the first ion exchange is in a range from about 5 hours to about 11 hours and the duration of the second ion exchange is in a range from about 10 minutes to about 45 minutes.

A seventeenth aspect according to any one of the fourteenth through sixteenth aspects, further comprising heating the glass-based substrate after filling and before performing the second ion exchange.

An eighteenth aspect according to any one of the fourteenth through seventeenth aspects, further comprising disposing a coating on a sidewall of the at least one hole after performing the first ion exchange and before filling, wherein the coating prevents migration of elements between the electrically conductive material and the glass-based substrate.

A nineteenth aspect according to any one of the fourteenth through eighteenth aspects, wherein the at least one hole is a through hole that extends from the first surface to the second surface.

A twentieth aspect according to any one of the fourteenth through nineteenth aspects, wherein the at least one hole is a blindhole.

A twenty-first aspect according to any one of the fourteenth through twentieth aspects, wherein the electrically conductive material is selected from the group consisting of copper, silver, aluminum, titanium, gold, platinum, nickel, tungsten, and magnesium.

A twenty-second aspect according to any one of the fourteenth through twenty-first aspects, wherein the glass-based substrate is glass or glass-ceramic.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is an exemplary glass-based article with at least one hole filled with an electrically conductive material;

FIG. 2 is an exemplary schematic representation of the compressive stress profile in a compressive stress region of a glass-based article disclosed herein;

FIG. 3 is schematic representation comparing the compressive stress profile in a compressive stress region of a glass-based article achieved through three different methods;

FIG. 4 is a top view of a glass-based article as it is treated according to an exemplary process of filling a through hole and then ion exchanging the article with the filled through hole;

FIG. 5 is a top view of a glass-based article as it is treated according to an exemplary process of ion exchanging the article with an unfill through hole, filling the through hole and then ion exchanging the article with the filled through hole;

FIG. 6A is a plan view of an exemplary electronic device incorporating any of the glass-based articles disclosed herein; and

FIG. 6B is a perspective view of the exemplary electronic device of FIG. 6A.

### DETAILED DESCRIPTION

Reference will now be made in detail to the present preferred embodiment(s), an examples of which is/are illustrated in the accompanying drawings. Whenever possible, the same reference numerals will be used throughout the drawings to refer to the same or like parts.

Generally, described herein is a glass-based article having at least one hole (either a through-hole or a blind-hole, or a combination thereof) wherein the at least one hole is filled with an electrically conductive material. The glass-based article has at least one region under compressive stress extending from a surface of the glass-based article to a depth of compressive stress layer, wherein the compressive stress is greatest at the surface. Also a cross-sectional area of the hole and a cross-sectional area of electrically conductive material differ by 0.1% or less. Having the greatest compressive stress at the surface provides mechanical strength and provides resistance to breaking resulting from sharp impacts or drops. Having the cross-sectional areas of the hole and the electrically conductive material differ by 0.1% or less means there is minimal spacial mismatch and thereby minimizes the possibility of the electrically conductive material delaminationg from the glass-based material. In some embodiments, these features (i.e., maximum compressive stress at the surface and a spacial mismatch between the cross-sectional areas of the hole and the electrically conductive material of 0.1% or less) may be achieved by ion exchanging the glass-based substrate a first time before filling the at least one hole, then filling the at least one hole with the electrically conductive material, and then ion exchanging the glass-based substrate a second time after filling the at least one hole.

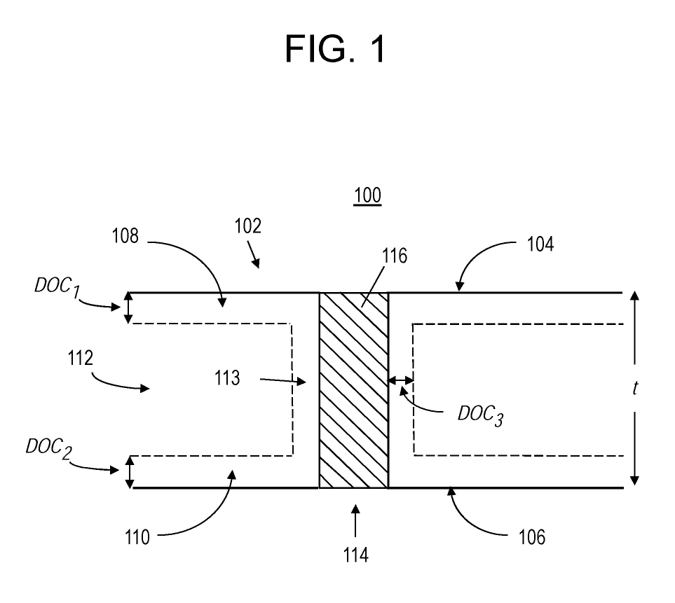

FIG. 1 illustrates an exemplary glass-based article 100 having a glass-based substrate 102, with a first surface 104, an opposing second surface 106, and a thickness t. As used herein, the term glass-based, includes both glasses and glass-ceramics. In some embodiments, glass-based substrate 102 may be strengthened such that it has a first region 108 under compressive stress (CS) extending from first surface 104 to a depth of compression (DOC) DOC₁. In some embodiments, the compressive stress in first region 108 is greatest at first surface 104. In some embodiments, glass-based substrate 102 may also have a second region 110 under compressive stress extending from second surface 106 to a depth of compression DOC₂. In some embodiments, the compressive stress in second region 110 is greatest at second surface 106. In some embodiments, a central region 112 of glass-based substrate 102 extends from DOC₁ to DOC₂ and is under central tension.

Glass-based substrate 102 may also have at least one hole 114 formed in the first surface 104 and extending into an interior of the substrate 102. In some embodiments, as shown in FIG. 1, hole 114 may be a through hole that extends from first surface 104 to second surface 106. In other embodiments, hole 108 may be a blind hole that extends from first surface 104 to some distance into substrate 102 but does not go all the way through to second surface 106. In some embodiments, there may only be through holes. In other embodiments, there may only be blind holes. In yet other embodiments, there may be a combination of through holes and blind holes. In some embodiments, the at least one hole 114 has a sidewall 113. In some embodiments, glass-based substrate 102 may be strengthened such that it has a third region 115 under compressive stress (CS) extending from sidewall 113 to a depth of compression DOC₃. In some embodiments, DOC₃ is smaller than DOC₁ and/or DOC₂. In other embodiments, DOC₃ is equal to DOC₁ and/or DOC₂.

In some embodiments, holes 114 may be filled with an electrically conductive material 116. In some embodiments, a cross-sectional area of hole 114 and a cross-sectional area of electrically conductive material 116 differ by 0.1% or less, 0.09% or less, 0.08% or less, or 0.07% or less. The cross-sectional area of the hole (Aₕₒₗₑ) and the cross-sectional area of the electrically conductive material (A_{con}) differ by 0.1% or less if (Aₕₒₗₑ−A_{con})/(Aₕₒₗₑ)≤0.001. Aₕₒₗₑ and A_{con} are measured at the surface using a scanning electron microscope.

Glass-based substrate 102 may include any glass-based material that is ion-exchangeable to be chemically strengthened. In some embodiments, the glass-based material is or contains an alkali aluminosilicate glass. In some embodiments, the thickness t of glass-based substrate 102 may be 2 mm or less, 1.5 mm or less, 1 mm or less, 0.9 mm or less, 0.8 mm or less, 0.7 mm or less, 0.6 mm or less, 0.5 mm or less, 0.4 mm or less, 0.3 mm or less, or 0.2 mm or less. In some embodiments, the thickness t of glass-based substrate 102 may be in a range from 0.1 mm to 2 mm, 0.1 mm to 1.5 mm, 0.1 mm to 1 mm, 0.2 mm to 2 mm, 0.2 mm to 1.5 mm, 0.2 mm to 1 mm, 0.5 mm to 2 mm, or 0.5 mm to 1.5 mm. While glass-based substrate 102 is shown in FIG. 1 as being flat, this is merely exemplary. In some embodiments, glass-based substrate 102 may be curved, bent, or otherwise shaped to be three-dimensional.

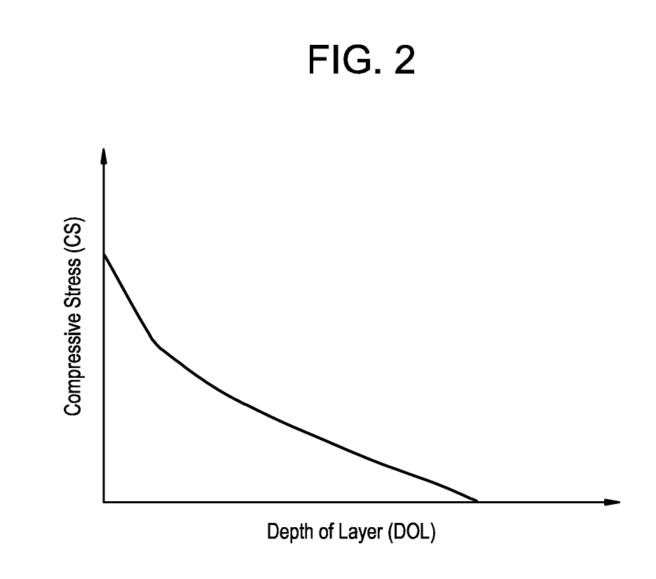

The compressive stress in first and second regions 108, 110 varies as a function of depth below the first and second surfaces 104, 106, respectively. FIG. 2 is an exemplary schematic representation of the compressive stress profile in first region 108 and/or second region 110, wherein the compressive stress is on the y axis and the depth is on the x axis. In some embodiments, as shown in FIG. 2, the compressive stress is greatest at the surface. In some embodiments, the compressive stress at the first and/or second surface 104, 106 is at least 100 megaPascals (MPa), at least 200 MPa, at least 300 MPa, at least 400 MPa, at least 500 MPa, at least 600 MPa, at least 700 MPa, at least 800 MPa, at least 900 MPa, at least 1,000 MPa, at least 1,100 MPa, or at least 1,200 MPa. In some embodiments, the compressive stress at the surface may be in a range from 100 MPa to 1,200 MPa, from 100 MPa to 1,000 MPa, 400 MPa to 1,200 MPa, from 400 MPa to 1,000 MPa, from 500 MPa to 1,200 MPa, from 500 MPa to 1,000 MPa, from 600 MPa to 1,200 MPa, from 600 MPa to 1,000 MPa, from 700 MPa to 1,200 MPa, or from 700 MPa to 1,000 MPa. In some embodiments, the DOC for first region 108 and/or second region is at least 20 μm, at least 30 μm, at least 40 μm, at least 50 μm, at least 60 μm, at least 70 μm, at least 80 μm, at least 90 μm, or at least 100 μm. In some embodiments, the DOC for first region 108 and/or second region is in a range from 20 μm to 100 μm, 30 μm to 100 μm, 40 μm to 100 μm, 50 μm to 100 μm, 60 μm to 100 μm, 70 μm to 100 μm, or 80 μm to 100 μm. In some embodiments, the DOC for first region 108 is less than or equal to 5%, less than or equal to 10%, less than or equal to 15%, or less than or equal to 20% of the thickness of glass-based substrate 102. In some embodiments, the DOC for second region 110 is less than or equal to 5%, less than or equal to 10%, less than or equal to 15%, or less than or equal to 20% of the thickness of glass-based substrate 102.

In some embodiments, holes 114 are created using a laser damage and etch process wherein a laser is utilized to create a damage region in the glass-based substrate 102 that may be a pilot hole or damage track and then the pilot hole or damage track is enlarged using an etching process. Exemplary ways for performing the laser damage creation and subsequent etching are disclosed in U.S. Pub. No. 2015/0166395 and U.S. Pat. No. 9,278,886, each of which is hereby incorporated by reference in its entirety. In some embodiments, holes 114 may have a largest diameter in a range from about 5 μm to about 150 μm, 5 μm to about 100 μm, 5 μm to about 50 μm, about 5 μm to about 20 μm, about 20 μm to about 150 μm, about 20 μm to about 100 μm, about 20 μm to about 50 μm, about 50 μm to about 150 μm, or about 50 μm to about 100 μm. In some embodiments, the largest diameter is at first surface 104 and/or second surface 106. Holes 114 may have a variety of shapes including, but not limited to, cylindrical, tapered, or hour-glass shaped. In some embodiments, holes 114 may be hour-glass shaped and have a waist (a point along the hole with the smallest diameter) wherein the waist has a diameter that is at least 50%, at least 55%, at least 60%, at least 65%, at least 70%, at least 75%, at least 80%, at least 85%, at least 90% or at least 95%. Diameters of the holes including can be measured by an optical microscope, for example.

In some embodiments, electrically conductive material 116 may be any suitable material that has a coefficient of thermal expansion (CTE) that exceeds that of the glass-based substrate. In some embodiments, electrically conductive material 116 may include, but is not limited to copper, silver, aluminum, titanium, gold, platinum, nickel, tungsten, or magnesium. In some embodiments, the conductive material may be a pure metal, a paste containing metal and glass filler particles, or a polymeric paste with metal filler particles. Holes 114 may be filled with electrically conductive material 116 using any known technique including, but not limited to sputtering, electrolytic plating, chemical vapor deposition, electrolysis, etc.

As noted above, glass-based substrate 102 is ion-exchangeable. The glass-based materials described hereinabove are chemically treated to provide a strengthened glass-based material. Ion exchange is widely used to chemically strengthen glass-based material. In one particular example, alkali cations within a source of such cations (e.g., a molten salt, or “ion exchange,” bath) are exchanged with smaller alkali cations within the glass-based material to achieve a layer that is under a compressive stress (CS) near the surface of the glass-based material. The compressive layer extends from the surface to a depth of compressive stress layer (DOC) within the glass. In the glass-based materials described herein, for example, potassium ions from the cation source are exchanged for sodium and/or lithium ions within the glass-based material during ion exchange by immersing the glass-based material in a molten salt bath comprising a potassium salt such as, but not limited to, potassium nitrate (KNO₃). Other potassium salts that may be used in the ion exchange process include, but are not limited to, potassium chloride (KCl), potassium sulfate (K₂SO₄), combinations thereof, and the like. The ion exchange baths described herein may contain alkali ions other than potassium and their corresponding salts. For example, the ion exchange bath may also include sodium salts such as sodium nitrate, sodium sulfate, sodium chloride, or the like.

Compressive stress is measured by surface stress meter (FSM) using commercially available instruments such as the FSM-6000, manufactured by Orihara Industrial Co., Ltd. (Japan). Surface stress measurements rely upon the accurate measurement of the stress optical coefficient (SOC), which is related to the birefringence of the glass. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety.

As used herein, DOC means the depth at which the stress in the chemically strengthened alkali aluminosilicate glass article described herein changes from compressive to tensile. DOC may be measured by FSM or a scattered light polariscope (SCALP) depending on the ion exchange treatment. Where the stress in the glass article is generated by exchanging potassium ions into the glass article, FSM is used to measure DOC. Where the stress is generated by exchanging sodium ions into the glass article, SCALP is used to measure DOC. Where the stress in the glass article is generated by exchanging both potassium and sodium ions into the glass, the DOC is measured by SCALP, since it is believed the exchange depth of sodium indicates the DOC and the exchange depth of potassium ions indicates a change in the magnitude of the compressive stress (but not the change in stress from compressive to tensile); the exchange depth of potassium ions in such glass articles is measured by FSM.

Glass-based substrate 102 with at least one hole 114 filled with an electrically conductive material 116 wherein a cross-sectional area of hole 114 and a cross-sectional area of electrically conductive material 116 differ by 0.1% or less and wherein glass-based substrate 102 has at least one region 110 or 112 under compressive stress where the maximum compressive stress in the region is at the surface may be formed according to the following method. First glass-based substrate having at least one hole 114 may be subjected to an ion-exchange process before at least one hole 114 is filled with electrically conductive material 116 to create a compressive stress region extending from first surface 104 and/or second surface 106. After the first ion exchange process, at least one hole 114 may be filled with electrically conductive material 116. Then after at least one hole 114 is filled, glass-based substrate 102 may be subjected to a second ion exchange process. As noted above, FIG. 2 illustrates an exemplary stress profile achieved in the compressive stress region after the second ion exchange process. In some embodiments, the first ion exchange process involves submersing glass-based substrate 102 in a molten salt ion exchange bath. The first ion exchange bath may include a mixture of about 45-70 wt % KNO₃ and about 30-55 wt % NaNO₃. In other embodiments, the first ion exchange bath may include a mixture of about 5 wt % or less NaNO₃ and the remainder KNO₃. In some embodiments, there may be a small amount (<5 wt %) of additives such as stabilizers and the like. In some embodiments, the first ion exchange may be performed at a temperature in a range from about 440° C. to about 470° C., for example about 440° C. about 450° C., about 460° C., or about 470° C. In some embodiments, the duration of the first ion exchange may be in a range from about 5 hours to about 11 hours, for example about 5 hours, about 6 hours, about 7 hours, about 8 hours, about 9 hours, about 10 hours, or about 11 hours. In some embodiments, the second ion exchange is performed at a lower temperature and/or duration than the first ion exchange. In some, embodiments the second ion exchange may be performed at a temperature in a range from about 380° C. to about 410° C., for example about 380° C., about 390° C., about 400° C., or about 410° C. In some embodiments, the duration of the second ion exchange may be in a range from about 10 minutes to about 45 minutes, for example about 10 minutes, about 12 minutes, about 15 minutes, about 18 minutes, about 20 minutes, about 22 minutes, about 25 minutes, about 28 minutes, about 30 minutes, about 32 minutes, about 35 minutes, about 38 minutes, about 40 minutes, about 42 minutes, or about 45 minutes. The second ion exchange bath may be the same or different from the first ion exchange bath. In some embodiments, the second ion exchange bath may include a mixture of about 5 wt % or less NaNO₃ and the remainder KNO₃, for example about 1 wt % NaNO₃ and about 99 wt % KNO₃. In some embodiments, there may be a small amount (<5 wt %) of additives such as stabilizers and the like.

In some embodiments, after the first ion exchange and before filling, a coating may be disposed on the sidewall of at least one hole 114 to prevent migration of elements between electrically conductive material 116 and glass-based substrate 102. In some embodiments, the coating may be silicon nitride. The coating may be applied using conventional techniques.

In some embodiments, after the filling and before the second ion exchange, the glass-based substrate may be subjected to a heat treatment. In some embodiments, the heating may occur at a temperature in a range from about 380° C. to about 410° C., for example about 380° C., about 390° C., about 400° C., or about 410° C. In some embodiments, the duration of the heating may be in a range from about 30 minutes to about 4 hours, for example about 30 minutes, about 1 hour, about 1.5 hours, about 2 hours, about 2.5 hours, about 3 hours, about 3.5 hours, or about 4 hours. In some embodiments, the method may include both the coating and heating steps.

The above-described method of performing a first ion exchange, then filling the at least one hole with an electrically conductive material, and then performing a second ion exchange provides advantaged attributes in the glass-based article over alternative methods. The advantaged attributes include a maximum CS at the surface, minimizing the spatial mismatch between the hole and the electrically conductive material such that the cross-sectional area of the electrically conductive material and the hole differ by less than 0.1%, and minimizing temperature induced stress between the glass-based substrate and the electrically conductive material.

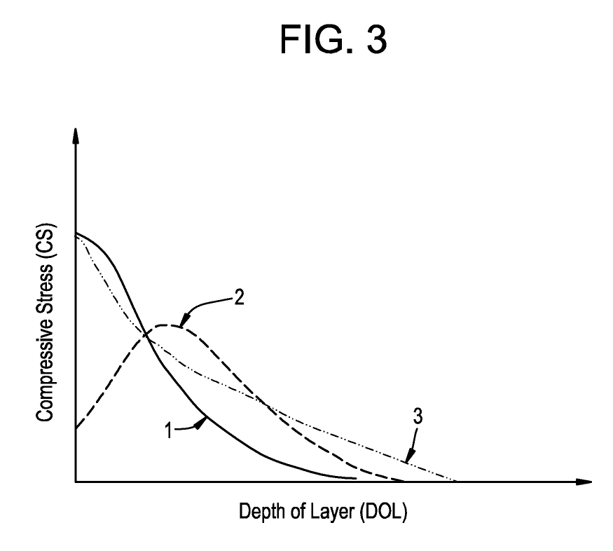

FIG. 3 is a schematic representation comparing the compressive stress profile that will be achieved in first region 108 and/or second region 110 of glass-based substrate 102 obtained according to three different methods. The compressive stress is on the y axis and the depth is on the x axis. Stress profile 1 illustrates what will be obtained by a process of filling the at least one hole with an electrically conductive material and then ion exchanging the filled glass-based substrate (“Process 1”). Stress profile 2 illustrates what will be obtained by a process of ion exchanging the glass-based substrate before filling the at least one hole with an electrically conductive material (“Process 2”). Stress profile 3 illustrates what will be obtained by the process described above of ion exchanging the glass-based substrate a first time, then filling the at least one hole with an electrically conductive material, and then ion exchanging the filled glass-based substrate a second time (“Process 3”). For each process a 0.7 mm thick glass substrate sample having through-holes with a diameter of about 80 μm and a composition of about 57.4 mol % SiO₂, about 16.1 mol % Al₂O₃, about 17.1 mol % Na₂O, about 2.8 mol % MgO, about 0.07 mol % SnO₂, and about 6.5 mol % P₂O₅ will be used. Through-holes will be filled with copper. To achieve stress profile 1, a glass sample will be ion exchanged in an ion exchange bath comprising about 95 wt % KNO₃ and about 5 wt % NaNO₃ at about 450° C. for about 5 hours. To achieve stress profile 2, a glass sample will be ion exchanged in an ion exchange bath comprising about 95 wt % KNO₃ and about 5 wt % NaNO₃ at about 450° C. for about 5 hours. To achieve stress profile 3, a glass sample will be ion exchanged before filling the through-holes in an ion exchange bath comprising about 95 wt % KNO₃ and about 5 wt % NaNO₃ at about 450° C. for about 5 hours. The glass will be allowed to cool to room temperature and then the through-holes were filled. After the through-holes are filled the glass will be ion-exchanged a second time exchanged in an ion exchange bath comprising about 99 wt % KNO₃ and about 1 wt % NaNO₃ at about 390° C. for about 30 mins.

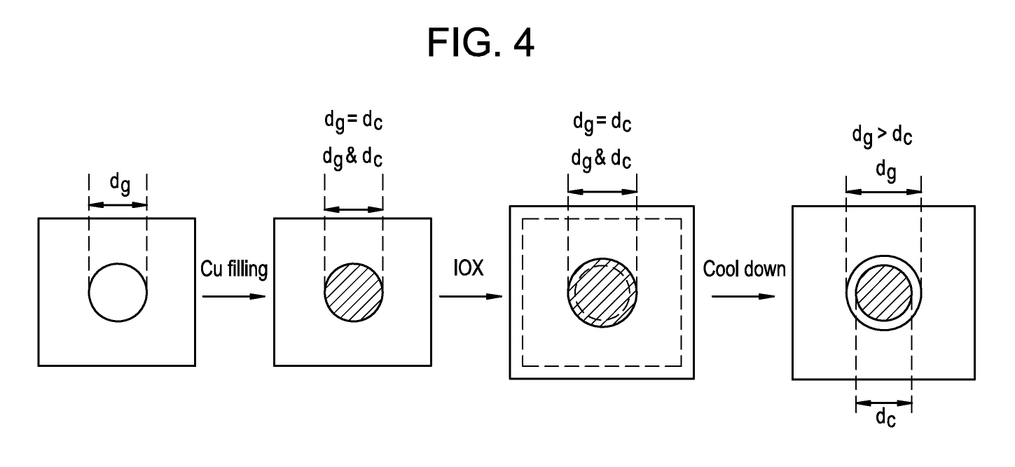

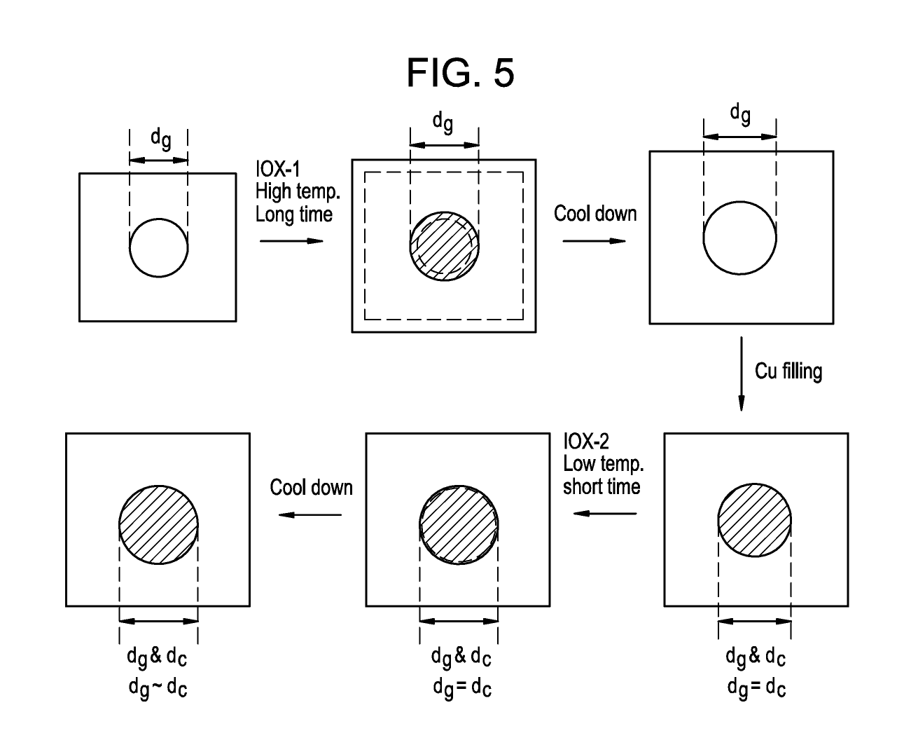

As described below, the article treated according to the process to achieve stress profile 3 will achieve the sought after characteristics. As can be seen by comparing stress profiles 1-3 in FIG. 3, stress profiles 1 and 3 have a maximum compressive stress at the surface, whereas stress profile 2 has a buried maximum compressive stress below the surface. As such, stress profile 3 has an advantage over stress profile 2 because having the maximum compressive stress at the surface aids in providing impact and scratch resistance to the glass. With respect to advantages of stress profile 3 over stress profile 1, it can be seen from FIG. 3, that stress profile 3 has a greater DOC than stress profile 1. Also, as demonstrated in FIGS. 4 and 5, articles treated according to Process 3 (ion exchange—fill—ion exchange) used to achieve stress profile 3 have an advantage over an article treated according to Process 1 (fill—ion exchange) used to achieve stress profile 1 in minimizing the differences in the cross-sectional area of the at least one hole and the cross-sectional area of the electrically conductive material by 0.1% or less.

FIG. 4 illustrates a top view of a glass substrate treated according to Process 1 used to achieve stress profile 1 in FIG. 3. Step a shows the glass substrate with an unfilled through hole having a diameter d_{g}. In step b, the through hole is filled with copper. The copper filling has a diameter and the diameters of the through hole and the copper filling are equal. In step c, the glass substrate with the filled through hole is ion exchanged and the glass substrate and copper filling expand as a result of the heating that occurs during the ion exchange step. The original perimeter of the through hole and copper filling are shown with a dashed line and after expansion the through hole and copper filling have the same diameter. The glass and the copper had different coefficients of thermal expansion—about 16.28×10⁻⁶/° C. for the copper and about 8.71×10⁻⁶/° C. for the glass composition that was used. The diameter of the through hole and the copper were believed to be the same after the ion exchange, the expansion of the copper (because of its higher coefficient of thermal expansion) caused the through-hole to expand at the same rate. This creates stress on the glass during the ion exchange process that can lead to cracks in the glass. To calculate the stress between the glass and the copper filling after ion exchange, it is assumed that the copper filling and the glass both only deform elastically and that no there was no stress between the glass and the copper filling after the filling step. The stress (σ) in MPa is calculated with the following equation:

σ=ΔT*(α_{Cu}−α_{glass})*[((1−v_{Cu})/E_{Cu})+(1−v_{glass})/E_{glass}]⁻¹ (1)

where:

ΔT is the difference between the ion exchange temperature and room temperature;

α_{Cu} is the coefficient of thermal expansion for the copper;

α_{glass} is the coefficient of thermal expansion for the glass;

v_{Cu} is Poisson's ratio for copper (here 0.35);

v_{glass} is Poisson's ratio for the glass (here 0.22);

E_{Cu} is Young's modulus for the copper in MPa (here 114,000 MPa)

E_{glass} is Young's modulus for the glass in MPa (here 65,800 MPa)

The stress for Process 1 using the copper, glass, and ion exchange temperature specified above was about 134.3 MPa. The stress would last for about the duration of the ion exchange (approximately 5 hours). In step d, the glass substrate and copper filling are allowed to cool to room temperature and the diameter of the glass d_{g} is larger than the diameter of the copper filling d_{c}. The copper filling is believed to return to its original shape, assuming the copper only deforms elastically by stress during the ion exchange. However, the ion exchange reaction changes the chemical composition of the glass such that the through-hole does not return to its original shape, it is bigger in dimension than the copper filling, and thereby creates a dimensional mismatch between the through hole and the copper filling. The dimensional mismatch can cause delamination of the copper filling from the glass through-hole.

FIG. 5 illustrates a top view of a glass substrate treated according to Process 3 used to achieve stress profile 3 in FIG. 3. Step a shows the glass substrate with an unfilled through hole having a diameter d_{g}. In step b the glass substrate with the unfilled through hole was ion exchanged and the diameter of the unfilled through hole expanded. The original perimeter of the through hole is shown with a dashed line. In step c, the ion-exchanged, unfilled through hole is allowed to cool down to room temperature and the diameter of the through-hole is larger than it was in step a because the ion exchange reaction changes the chemical composition of the glass such that the through-hole does not return to its original shape. In step d, the through hole is filled with copper. The copper filling has a diameter d_{c} and the diameters of the through hole and the copper filling are equal. In step e, the glass substrate with the filled through hole is ion exchanged and the glass substrate and copper filling expand as a result of the heating that occurs during this second ion exchange step. The original perimeter of the through hole and copper filling are shown with a dashed line and after expansion the through hole and copper filling have the same diameter. As noted above, the glass and the copper had different coefficients of thermal expansion. The diameter of the through hole and the copper were believed to be the same after the second ion exchange, the expansion of the copper (because of its higher coefficient of thermal expansion) caused the through-hole to expand at the same rate. This created stress on the glass during the second ion exchange process that could lead to cracks in the glass. The stress for Process 3 using the copper, glass, and ion exchange temperature specified above was calculated to be about 115.5 MPa using equation (1) above and would last for the duration of the second ion exchange (about 30 mins). The stress was lower than the 134.3 MPa created in Process 1 and would last much less than that experienced from Process 1. In step f, the glass substrate and copper filling are allowed to cool to room temperature and the diameter of the glass d_{g} is approximately the same diameter of the copper filling d_{c}. Although, the second ion exchange reaction changes the chemical composition of the glass the second ion exchange occurs for a short period of time such that there is minimal dimensional mismatch the through-hole and copper filling as opposed to Process 1.

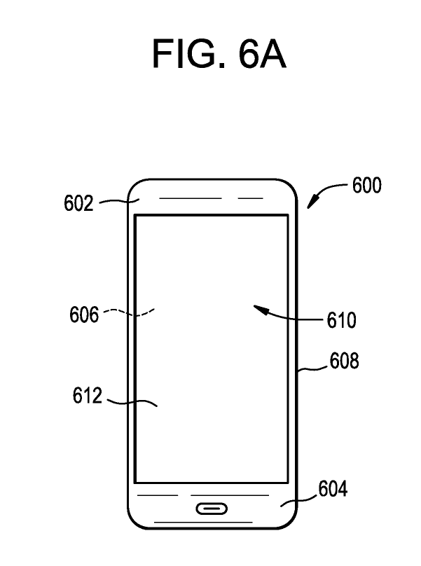

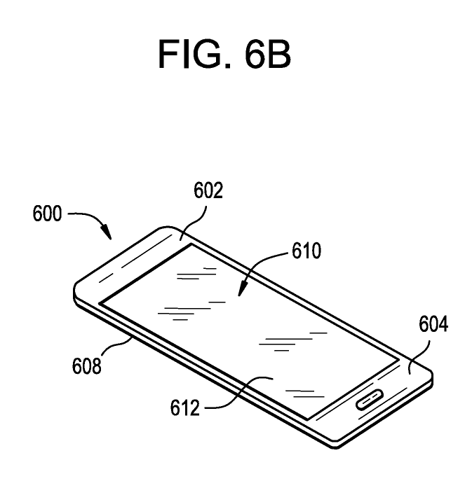

The glass-based articles disclosed herein may be incorporated into another article such as an article with a display (or display articles) (e.g., consumer electronics, including mobile phones, tablets, laptops, computers, navigation systems, and the like). An exemplary article incorporating any of glass-based articles disclosed herein is shown in FIGS. 6A and 6B. Specifically, FIGS. 6A and 6B show a consumer electronic device 600 including a housing 602 having front 604, back 606, and side surfaces 608; electrical components (not shown) that are at least partially inside or entirely within the housing and including at least a controller, a memory, a fingerprint sensor or touchscreen and a display 610 at or adjacent to the front surface of the housing; and a cover substrate 612 at or over the front surface of the housing such that it is over the display. In some embodiments, the cover substrate 612 may include any of the glass-based articles disclosed herein that have been ion exchanged and have holes 614 filled with an electrically conductive material that provides a conductive pathway for use as part of a fingerprint sensor and/or touchscreen.

It will be apparent to those skilled in the art that various modifications and variations can be made without departing from the spirit or scope of the invention.

1. A glass-based article comprising:
a glass-based substrate comprising a first surface, a second surface opposing the first surface, at least one hole formed in the first surface, and a region under a compressive stress extending from the first surface to a depth of compression DOC₁ in the glass-based substrate, wherein the compressive stress in the region is greatest at the first surface; and
an electrically conductive material disposed in the at least one hole, wherein a cross-sectional area of the at least one hole and a cross-sectional area of the electrically conductive material differ by 0.1% or less.

2. The glass-based article of claim 1, wherein the coefficient of thermal expansion (CTE) of the electrically conductive material is higher than the CTE of the glass-based substrate.

3. The glass-based article of claim 1, wherein the compressive stress of the glass-based substrate at the first surface is greater than or equal to about 100 MPa.

4. The glass-based article of claim 1, wherein the compressive stress of the glass-based substrate at the first surface is in a range from about 100 MPa to about 1,200 MPa.

5. The glass-based article of claim 1, wherein the at least one hole is a through hole that extends from the first surface to the second surface.

6. The glass-based article of claim 1, wherein the at least one hole is a blindhole.

7. The glass-based article of claim 1, wherein the electrically conductive material is selected from the group consisting of copper, silver, aluminum, titanium, gold, platinum, nickel, tungsten, and magnesium.

8. The glass-based article of claim 1, wherein the DOC₁ is at least 20 μm.

9. The glass-based article of claim 1, further comprising a second region of compressive stress extending from the second surface to a second depth of compression DOC₂.

10. The glass-based article of claim 9, further comprising a region of central tension located between the regions of compressive stress.

11. The glass-based article of claim 1, wherein the glass-based substrate is glass.

12. The glass-based article of claim 1, wherein the glass-based substrate is glass-ceramic.

13. A consumer electronic product, comprising:
a housing having a front surface, a back surface and side surfaces;
electrical components provided at least partially within the housing, the electrical components including at least a controller, a memory, a fingerprint sensor, and a display, the display being provided at or adjacent the front surface of the housing; and
the glass-based article of any preceding claim disposed over the display, wherein the electrical conductive material provides a conductive pathway for the fingerprint sensor.

14. A method of producing a glass-based article, the method comprising:
performing a first ion exchange of a glass-based substrate, the glass-based substrate comprising a first surface, a second surface opposing the first surface, and at least one hole formed in the first surface to create a region under a compressive stress extending from the first surface to a depth of compression DOC in the glass-based substrate;
filling the at least one hole with an electrically conductive material after ion exchanging the glass-based substrate; and
performing a second ion exchange of the glass-based substrate after filling the at least one hole.

15. The method of claim 14, wherein a duration of the second ion exchange is shorter than a duration of the first ion exchange.

16. The method of claim 15, wherein the duration of the first ion exchange is in a range from about 5 hours to about 11 hours and the duration of the second ion exchange is in a range from about 10 minutes to about 45 minutes.

17. The method of claim 14, further comprising heating the glass-based substrate after filling and before performing the second ion exchange.

18. The method of claim 14, further comprising disposing a coating on a sidewall of the at least one hole after performing the first ion exchange and before filling, wherein the coating prevents migration of elements between the electrically conductive material and the glass-based substrate.

19. The method of claim 14, wherein the at least one hole is a through hole that extends from the first surface to the second surface.

20. The method of claim 14, wherein the at least one hole is a blindhole.

21. The method of claim 14, wherein the electrically conductive material is selected from the group consisting of copper, silver, aluminum, titanium, gold, platinum, nickel, tungsten, and magnesium.

22. The method of claim 14, wherein the glass-based substrate is glass or glass-ceramic.
